(19) United States
(12) Patent Application Publication
(10) Pub. No.: US 2014/0218095 A1
(43) Pub. Date: Aug. 7, 2014

(54) SIGNAL REGULATION DEVICE FOR AN OXYGEN SENSOR

(71) Applicant: JIM TECHNOLOGY CO., LTD., Kaohsiung (TW)

(72) Inventor: CHENG HSING CHIEN, Kaohsiung (TW)

(73) Assignee: JIM TECHNOLOGY CO., LTD., Kaohsiung (TW)

(21) Appl. No.: 14/165,766

(22) Filed: Jan. 28, 2014

(30) Foreign Application Priority Data
Feb. 6, 2013 (TW) 102202535

(51) Int. Cl. H03K 6/00

(52) U.S. Cl. CPC H03K 6/00
USPC 327/306

(57) ABSTRACT

The present disclosure presents a signal regulation device for an oxygen sensor which features a voltage regulation module connected between an automobile system and an oxygen sensor in series through an input module and an output module, changing initial voltage generated by the oxygen sensor, transmitting regulated voltage to the automobile system via the output module, and interfering with a catalytic converter for processed oxygen content to be detected by the oxygen sensor.

### BACKGROUND OF THE INVENTION

1) Field of the Invention

The present disclosure presents a device used in regulating an oxygen sensor's output voltage, particularly a device installed between an automobile system and the oxygen sensor in series and capable of regulating the oxygen sensor's output voltage within a default voltage range.

2) Description of the Prior Art

The existing on-board diagnosis systems had been applicable to automobiles in U.S. since the mid-1980s. The on-board diagnosis system featured oxygen sensors sending error signals with an automobile's exhaust out of control limits detected by an air fuel ratio control system. The on-board diagnosis system which was gradually developed as one system with various control components competent in monitoring exhaust for early detection of pollution out of limits has been provided with oxygen sensors in each vehicle.

The oxygen sensors are basically located at a catalytic converter's front and rear sections at which the concentration differences of oxygen or any hazardous substance before and after treatment can be detected for an automobile's combustion states conforming to a nation's environmental regulations.

An on-board computer is able to check oxygen content in exhaust from an engine and regulate fuels to be injected for control of hazardous substances after receiving voltage signals from oxygen sensors.

The oxygen sensor based on concentration differences of oxygen at 400 degrees Celsius is able to generate electromotive force (emf) and further voltage which is attenuated (enhanced) when the oxygen concentration in a tailpipe ascends (descends). With information of oxygen concentrations provided, the on-board computer decides an engine's air fuel ratio, reducing fuel supply for environmental protection.

However, the fuels supplied by the on-board computer based on feedback voltages of oxygen sensors should refer to the manufacturer's built-in program which is immune to a user's interference and unchanged with any vehicle component replaced. On the other hand, an alternative to reduce fuel supply for lower fuel consumption of an automobile running at low speeds and the original driving status of an automobile with its catalytic converter failed are unavailable.

Furthermore, the other problem is to regulate feedback voltage from an oxygen sensor in an existing automobile on the premise that an on-board computer is kept unchanged under restriction of regulations.

### SUMMARY OF THE INVENTION

To solve the above problem, the present disclosure presents a signal regulation device for an oxygen sensor which comprises a voltage regulation module connected between an automobile system and an oxygen sensor in series through an input module and an output module, changing initial voltage generated by the oxygen sensor, and transmitting regulated voltage to the automobile system via the output module for an adjusted air fuel ratio.

The object of the present disclosure is to provide a signal regulation device for an oxygen sensor which is effective in regulating voltage from an oxygen sensor.

The other object of the present disclosure is to provide a signal regulation device for an oxygen sensor which is connected between an automobile system and an oxygen sensor in series for fast interference with an on-board computer for regulation of an air fuel ratio.

The further object of the present disclosure is to provide a signal regulation device for an oxygen sensor with probe holes thereon to easily test initial output voltage in contrast to a conventional oxygen sensor without probe holes.

The yet other object of the present disclosure is to provide a signal regulation device for an oxygen sensor with probe holes thereon for fast detection and regulation of output voltage without a requirement of an external vehicle diagnosis system.

The yet still other object of the present disclosure is to provide a signal regulation device for an oxygen sensor which comprises a regulation unit used to quickly adjust a voltage regulation module's resistance, change output voltage of an oxygen sensor, and interfere with an on-board computer for detection of a catalytic converter's effect.

The technical measures in the present disclosure for the above purposes are shown as follows. A signal regulation device for an oxygen sensor in the present disclosure comprises a voltage regulation module and an input module and an output module, both of which are electrically connected to the voltage regulation module, and is characterized in that voltage is received by the input module electrically connected to an oxygen sensor port and transmitted to the voltage regulation module and further the automobile system from the output module.

The other technical measures in the present disclosure are further presented as follows.

In the signal regulation device for an oxygen sensor, the voltage regulation module comprises a regulation unit.

In the signal regulation device for an oxygen sensor, the input module has a first probe hole.

In the signal regulation device for an oxygen sensor, the output module has a second probe hole.

In contrast to the prior art, a signal regulation device for an oxygen sensor in the present disclosure is effective in: (1) fast verifying initial voltage; (2) quickly verifying regulated voltage; (3) saving time in installation with the signal regulation device installed between an automobile system and an oxygen sensor in series; (4) flexible installation in any existing vehicle model because of its universal interface.

BRIEF DESCRIPTIONS OF THE DRAWINGS

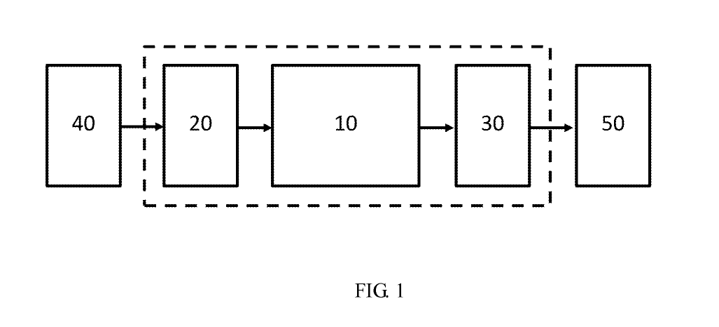

FIG. 1 illustrates the first architecture of the present disclosure.

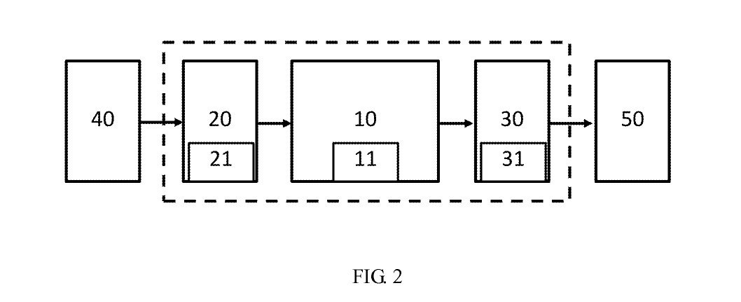

FIG. 2 illustrates the second architecture of the present disclosure.

### DETAILED DESCRIPTIONS OF THE PREFERRED EMBODIMENTS

The purposes, features and effects of a signal regulation device for an oxygen sensor are particularly disclosed in the preferred embodiments as follows.

FIGS. 1 and 2 illustrate main architecture of a signal regulation device for an oxygen sensor in the present disclosure. Please refer to FIG. 1 which illustrates a signal regulation device for an oxygen sensor comprises a voltage regulation module (10), an input module (20) and an output module (30).

As shown in FIG. 1, the input module (20) and the output module (30) are electrically connected to an oxygen sensor port (40) and an automobile system (50), respectively. When a car engine is started and runs at operating temperature, the oxygen sensor which refers to a concentration difference of oxygen in atmosphere and a tailpipe generates electromotive force and voltage between 0 and 1 Volt detected from the oxygen sensor port (40).

As shown in FIG. 1, the input module (20) transmits output voltage from the oxygen sensor port (40) to the voltage regulation module (10) which regulates the output voltage by referring to a default voltage step-down configuration; the regulated voltage is transmitted to the output module (30) from the voltage regulation module (10).

As shown in FIG. 1, the output module (30) transmits voltage regulated by the voltage regulation module (10) to an automobile system (50); an on-board computer receiving the regulated voltage decides fuels to be injected by comparing the regulated voltage and the default voltage defined in a built-in program; alternatively, the function to monitor a catalytic converter with an on-board computer can be intervened by referring to a regulated voltage received by the on-board computer via the automobile system (50).

Specially, the voltage regulation module (10) is either a resistor module, that is, an electronic or electrical device with resistors installed, or a biasing module. The input module (20) or the output module (30) comprises at least two heating lines, a signal line and a ground line, each of which has male and female connectors, for electrical connections between the automobile system and the oxygen sensor in series wherein the signal line and the heating lines are used to transmit signals and electricity to heat the oxygen sensor, respectively.

Preferably, the voltage regulation module (10) as shown in FIG. 2 comprises a regulation unit (11) and the input module (20) and the output module (30) have a first probe hole (21) and a second probe hole (31), respectively. The regulation unit (11) which depends on a Variable Resistor (VR) in the voltage regulation module (10) regulates an output voltage curve for voltages from the oxygen sensor port (40) to meet customized requirements. The first probe hole (21) is used to link a tester which is capable of quickly sampling initial output voltage from the oxygen sensor; the second probe hole (31) is used to link a tester which is competent in quickly sampling regulated voltage.

The details of a signal regulation device for an oxygen sensor in the present disclosure are further described in a preferable embodiment as follows.

Please refer to FIG. 2 which illustrates the input module (20) and the output module (30) in the present disclosure are electrically connected to the oxygen sensor port (40) and the automobile system (50), respectively; the oxygen sensor, which has been electrically heated to operating temperature, depends on electromotive force to generate voltage which is further transmitted to the voltage regulation module (10) from the input module (20).

For a high air fuel ratio and oxygen content in a tailpipe reduced: an output voltage from the oxygen sensor port (40) approaching 1 Volt is detected via the first probe hole (21); the output voltage transmitted to the voltage regulation module (10) is reduced to 0.7 Volt; an on-board computer receiving the regulated voltage transmitted to the automobile system (50) from the output module (30) regulates fuels to be injected which are less than those at an output voltage approaching 1 Volt for upgrade of an automobile's power.

Alternatively, the output voltage from the oxygen sensor port (40) under interference of the voltage regulation module (10) can be changed by a user who employs the regulation unit (11). For a high air fuel ratio and oxygen content in a tailpipe reduced: an output voltage from the oxygen sensor port (40) approaching 1 Volt is detected via the first probe hole (21); the output voltage in the voltage regulation module (10) is reduced to 0.5 Volt by the regulation unit (11); the 0.5 Volt transmitted to the output module (30) and the automobile system (50) is verified via the second probe hole (31); an on-board computer receiving the regulated voltage regulates fuels to be injected which are much less than those at an output voltage approaching 1 Volt for further upgrade of an automobile's power.

For a normal air fuel ratio and oxygen content in a tailpipe reduced: an output voltage from the oxygen sensor port (40) approaching 0.6 Volt is detected via the first probe hole (21); the output voltage in the voltage regulation module (10) is regulated to 0.8 Volt by the regulation unit (11); the 0.8 Volt transmitted to the output module (30) and the automobile system (50) is verified via the second probe hole (31); an on-board computer receiving the regulated voltage regulates fuels to be injected for less fuel consumption of an automobile.

Moreover, a vehicle with its catalytic converter acting abnormally will avoid low efficiency temporarily because the function to monitor a catalytic converter with an on-board computer is intervened by referring to a regulated voltage received by the on-board computer via the automobile system (50), for example, an output voltage of the oxygen sensor port (40), 1 Volt (or lower than 0.5 Volt based on a realistic situation) detected through a probe hole (21), is changed to 0.5 Volt (or 0.7 Volt based on specifications of an automobile) by the voltage regulation module (10).

A signal regulation device for an oxygen sensor in the present disclosure, which differs from a conventional method to remove an oxygen sensor from its original position, features a self-defined air fuel ratio for lower fuel consumption control and applications for an oxygen sensor is referred to as creative work that meets patentability and is applied for the patent.

It should be reiterated that the above descriptions presents preferred embodiments, and any equivalent change in specifications, claims, or drawings still belongs to the technical field within the present disclosure with reference to claims hereinafter.

What is claimed is:

1. A signal regulation device for an oxygen sensor, comprising a voltage regulation module (10) and an input module (20) and an output module (30), both of which are electrically connected via said voltage regulation module (10); characterized in that said input module (20) electrically connected to an oxygen sensor port (40) transmits received voltage to said voltage regulation module (10) for regulation and further an automobile system (50) via said output module (30).

2. A signal regulation device for an oxygen sensor according to claim 1 characterized in that said voltage regulation module (10) comprises a regulation unit (11).

3. A signal regulation device for an oxygen sensor according to claim 1 characterized in that said input module (20) has a first probe hole (21).

4. A signal regulation device for an oxygen sensor according to claim 1 characterized in that said output module (30) has a second probe hole (31).
